(19) United States
(12) Patent Application Publication
(10) Pub. No.: US 2026/0140158 A1
(43) Pub. Date: May 21, 2026

(54) TEST ENVIRONMENT AND COMPUTER-IMPLEMENTED METHOD FOR VERIFYING A COMMUNICATION

(71) Applicant: dSPACE GmbH, Paderborn (DE)

(72) Inventors: Jan Gibert, Paderborn (DE); Prashanth Hariharasubramanian, Paderborn (DE)

(21) Appl. No.: 19/369,383

(22) Filed: Oct. 27, 2025

(30) Foreign Application Priority Data
Oct. 29, 2024 (DE) 102024131539.3

(51) Int. Cl. G01R 31/00; H04J 3/06

(52) U.S. Cl. CPC G01R 31/006; H04J 3/0667

(57) ABSTRACT

A test system for testing a device under test includes: an interface configured to exchange messages with the device under test over a communication channel in order to test the device under test; and a processor configured to verify whether at least one message exchanged over the communication channel corresponds to a specification, wherein the specification comprises stored specification messages. The verification comprises storing the messages exchanged over the communication channel as memory messages, and the verification is carried out using at least one memory message and at least one specification message.

### CROSS-REFERENCE TO PRIOR APPLICATIONS

This application claims benefit to German Patent Application No. DE 102024131539.3, filed on Oct. 29, 2024, which is hereby incorporated by reference herein.

### FIELD

The application relates to a test environment for a device under test, to a computer-implemented method for verifying a communication, to a computer program for carrying out the method, and to a computer-readable data medium on which the computer program is stored.

### BACKGROUND

There are methods for testing and validating functions and systems, including for at least partially self-driving vehicles and for other vehicles and machines in various sectors. One testing option is to facilitate electronic stimulation of the functions to be tested by reproducing data from real-world situations or test trips. Depending in particular on the stage of development of the functions, these functions can, for example, be provided purely as software and/or in vehicle components, e.g., as a function of a control unit. The stimulation can in particular be carried out by a communication over a communication channel, as also takes place in real-world situations. In this way, the function can be checked and validated over the communication channel.

In this process, the function can be implemented on the device under test, which interacts with its surroundings via the communication over the communication channel. The elements of the device under test that are to be tested can comprise software and/or hardware. The device under test can be tested accordingly, e.g., as a virtual control unit in a software-in-the-loop method or as a real control unit in a hardware-in-the-loop method.

### SUMMARY

In an exemplary embodiment, the present disclosure provides a test system for testing a device under test. The test system includes: an interface configured to exchange messages with the device under test over a communication channel in order to test the device under test; and a processor configured to verify whether at least one message exchanged over the communication channel corresponds to a specification, wherein the specification comprises stored specification messages. The verification comprises storing the messages exchanged over the communication channel as memory messages, and the verification is carried out using at least one memory message and at least one specification message.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 is a schematic block diagram of a test environment with a device under test connected;

FIG. 2 is a flowchart of a schematic overview of a first embodiment of a method for verifying a communication;

FIG. 3 is a flowchart of a schematic overview of a second embodiment of a method for verifying a communication;

FIG. 4 is a flowchart of a schematic overview of a third embodiment of a method for verifying a communication;

FIG. 5 is a flowchart covered by the third embodiment;

FIG. 6 is a further flowchart covered by the third embodiment; and

FIG. 7 is a further flowchart covered by the third embodiment.

### DETAILED DESCRIPTION

A test environment for a device under test exchanges messages with the device under test over a communication channel. The test environment is configured to verify whether at least one message exchanged over the communication channel corresponds to a specification, the specification comprising stored specification messages and the verification comprising storing the messages exchanged over the communication channel as memory messages. The verification is carried out using at least one memory message and at least one specification message.

The test environment is configured to test the device under test, the exchange of messages with the device under test over the communication channel being used to test the device under test.

A computer-implemented method for verifying a communication comprises:
reading out memory messages, the memory messages comprising stored messages exchanged with a device under test over a communication channel in order to test the device under test,
verifying whether at least one message exchanged over the communication channel corresponds to a specification, the specification comprising stored specification messages and the verification being carried out using at least one memory message and at least one specification message.

This allows for a simple solution for validating messages exchanged between the test environment and the device under test. A relationship can be established between the memory message and the specification message in a simple manner. This can provide an improved match rate with regard to the correspondence between the specification message and the memory message. In this application, “match” refers to the closest possible correspondence or the complete correspondence between the memory message and the specification message. The reliability of both the test environment and the method in terms of their functioning can be verified and improved.

The method can be used to test the device under test or to validate the test environment. The method provides the option of associating the two data streams, i.e., the memory messages and the specification messages, with one another.

The “test environment” refers to an environment which can be used to comprehensively check the device under test, for example either a development stage of an item of software or a control unit, in terms of its function. In this case, the device under test could be provided as hardware but also as software. If the device under test is configured as hardware, this is called hardware in the loop, which is abbreviated to HIL.

If the device under test is merely provided in software which runs on a processor for general applications or the like, this can be referred to as software in the loop, which is abbreviated to SIL. Such a software-in-the-loop test makes it possible to test even early development stages of a function without the specific hardware, e.g., the control unit, having to already be available for testing. Such a configuration of the test environment can be configured such that it is specially tailored to a device under test, regardless of whether the functionality is implemented as software and/or hardware.

In addition to communication interfaces, the test environment in particular comprises a computer or a plurality of computers which execute the steps required for testing the device under test. In addition to electronic interfaces, however, the test environment can also comprise mechanical interfaces so that, for example, a device under test, in particular a hardware device under test, can be easily installed for connection to the test environment.

“Testing the device under test” can be understood to mean checking various functionalities of the device under test. As a result, the number of test trips in particular can then be significantly reduced.

The “communication channel” can, for example, be understood to be a data bus connection, e.g., a controller area network (CAN) bus or an Ethernet connection. These data transmission channels can in particular be wired. It is, however, also possible to form the communication channel to be wireless.

A “message” is understood, for example, to be a data frame or data packet which has a predetermined length having a predetermined section for payload data. However, the data communication may also alternatively be configured to be continuous, for example in power-line data transmission.

The communication is verified in comparison with the specification. It is thus possible to verify whether the specification or parts of the specification are used in the communication of the test environment with the device under test. The specification comprises the specification message. The message exchanged between the device under test and the test environment is in the form of a memory message. The memory message is read out and compared with at least one stored specification message. The comparison is used to determine whether a message corresponding to the specification message has been exchanged with the device under test in the communication over the communication channel. In this case, the stored specification messages comprise e.g., the originals which arose and were recorded during a test trip, for example.

The specification messages can accordingly comprise messages which can be construed by the device under test as originating from its physical environment, i.e., as environment messages. The device under test can then be stimulated by those environment messages which correspond to certain specification messages. For example, these environment messages can therefore be messages which have been sent from a sensor to a control unit, such that using these environment messages it can be checked whether a control unit to be tested responds correctly to such sensor messages.

The exchanged messages are stored by the test environment as memory messages. The memory messages thus comprise the messages exchanged between the test environment and the device under test over the communication channel. In this case, the test environment can store both the data sent by it (environment messages) and the data sent by the device under test (device-under-test messages). This further improves the possibility of determining the accuracy of the messages.

Messages can be lost during transmission over the communication channel. The loss of these messages can be ascertained by the described test environment or the described method. The nature of a message can have been altered by interference, for example other messages, crosstalk from other communication channels, noise, etc. Any such alteration to these messages can also be ascertained by the described test environment or the described method.

The memory messages are stored in an electronic memory, for example. However, other memory technologies can also be used.

In one embodiment, it is provided that the messages comprise environment messages and device-under-test messages. In this case, the test environment is configured to send the environment messages and to receive the device-under-test messages from the device under test. As a result, an exchange of messages can be implemented. The device under test can be stimulated by the environment messages for test purposes. Its device-under-test messages, transmitted as a response thereto, can be verified for the purposes of testing the device under test, and conclusions can be drawn on the functionality of the device under test.

In one embodiment, to stimulate the device under test by the specification messages, those messages which constitute environment data for the device under test are sent by the test environment as stimulus data for the device under test. In this embodiment, the at least one memory message is an environment message, i.e., a message which has been sent by the test environment to the device under test. This allows the sent message to be compared with the original message (specification message) to determine whether the environment message corresponds to the specification message or, for example, has been impaired by some effect during sending.

In one embodiment, the test environment is configured to use a PTP protocol for exchanging the messages over the communication channel. “PTP protocol” is short for Precision Time Protocol and is a network protocol that synchronizes a time setting of a plurality of units in a computer network. The PTP protocol is used in particular in locally limited networks when high accuracy is required.

In one embodiment, the at least one specification message is read out from a first memory and is sent over the communication channel as an environment message. The test environment can be configured to read out at least one specification message from a first memory and send it over the communication channel as a message. While sending the environment message, interference caused by other messages or other sources of interference, as set out above, can occur. Such interference can be ascertained by the test environment or the method.

In this embodiment, communication messages recorded during a test trip, for example, can thus be saved in the first memory as specification messages. They are then read out from the first memory by the test environment and sent to the device under test over the communication channel as environment messages. In this way, the device under test can be subject to communication over the communication channel as would be the case on a test trip or real trip.

In embodiments, the verification can be carried out using a time indication in the at least one memory message and in the at least one specification message. In this embodiment, the test environment is configured to carry out the verification using a time indication in the at least one memory message and in the at least one specification message. The time indication can comprise a time stamp, for example. The verification can be improved in a simple manner by the time indication or time stamp. For example, the time indication can contain the time stamp having time information about when the message in question was sent on the communication channel.

Furthermore, the verification can be carried out using the content of the at least one memory message and of the at least one specification message. Therefore, in addition to the time information, the content of the data can also be used for the comparison. In particular, the content can be compared to establish whether the compared messages carry the same content. The content of messages can also be referred to as the payload. The content of messages is carried in the message together with management information. This management information relates to information for sending and processing the messages in accordance with a communication protocol. The content of messages relates to the payload.

In embodiments, it can be provided that the verification comprises associating the at least one memory message with the at least one specification message. In this process, messages having the same content can be associated with one another, for example. In this case, association comprises identifying the specification message within the memory messages; in other words, via the association, the specification message is identified in the stream of the recorded communication between the device under test and the test environment.

In particular, it can be provided that the verification is carried out iteratively using a plurality of memory messages and a plurality of specification messages, a particular memory message and a particular specification message being used in an iteration. Therefore, over a plurality of iteration steps, a plurality of memory messages and specification messages can be compared with one another to find those messages that have the best correspondence between the memory message and the specification message. To do this, lists of memory messages and specification messages can be used, for example.

In embodiments, it can be provided that, in an iteration, a difference is established between the respective time indications of the memory message and the specification message, and, on the basis of a sign of the difference, the relevant memory message or the relevant specification message is used for a further iteration. By establishing this difference between the respective time indications, an efficient comparison can be carried out.

In one embodiment, the particular memory message or the particular specification message is discarded if the difference between the time indications is above a threshold value. In such a case, the time difference is too great and demonstrates that there is no relationship between such a memory message and a corresponding specification message.

For example, the association between the memory message and the specification message is determined when the sign of differences changes in successive iterations. This indicates that a minimum has thus been found for the differences. There is a match.

A computer program comprises commands which, when the program is executed by a computer, cause said computer to carry out the described method for verifying a communication. The computer program can e.g., be stored on a computer-readable data medium. To do this, the computer-readable data medium has suitable storage options.

Embodiment examples of the application are shown in the drawings and explained in greater detail in the following description.

In the drawings, the same reference signs are used for the same or similar elements. The views in the drawings may not be to scale.

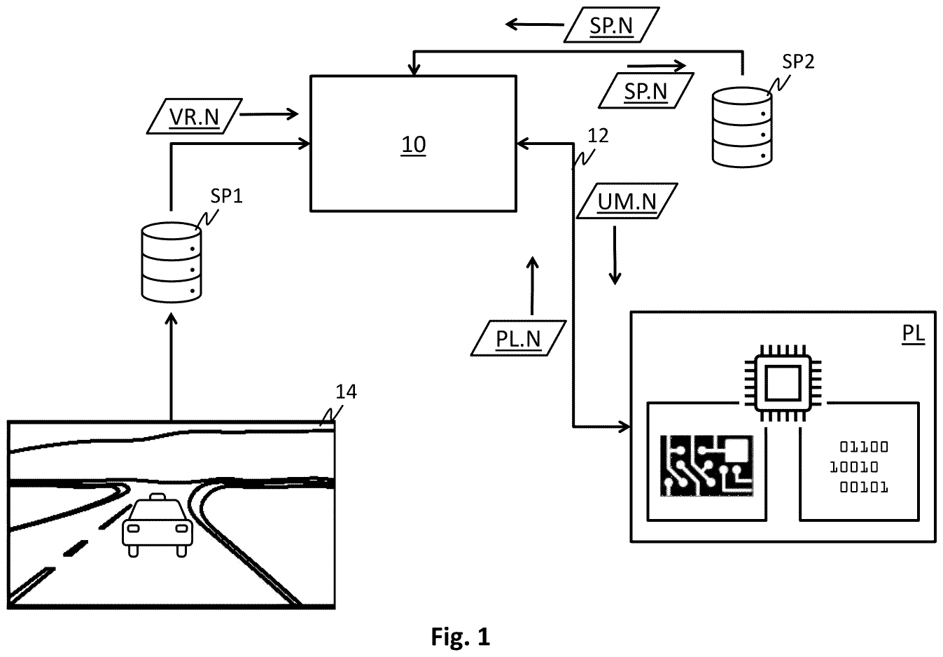

FIG. 1 is a schematic block diagram of a test environment 10 with a device under test PL connected to the test environment 10 over a communication channel 12.

A first memory SP1 and a second memory SP2 are connected to the test environment 10. Messages from a recording of a test trip 14 are stored in the first memory SP1. These messages are used as specification messages VR.N and are provided for stimulating the device under test PL over the communication channel 12, in particular as so-called replay data.

The second memory SP2 is used to store the so-called memory messages SP.N but also to read out these memory messages SP.N for comparison with the specification messages VR.N.

The first and the second memory SP1, SP2 can be part of the test environment 10 or can be separate from the test environment 10. There can also be a combination of both configurations. In particular, a single storage medium can also be used for the two memories SP1 and SP2, i.e., the distinction is then only software-based and not physical, for example.

The communication channel 12 can be configured as a data bus line, for example. For this purpose, an Ethernet bus connection can be provided, for example. However, other data connections are also possible, for example a point-to-point connection. In this case, wired communication channels or wireless communication channels can be provided. For a device under test PL from the automotive sector, a data bus as also found in a vehicle, e.g., CAN, local interconnect network (LIN), etc., can in particular be provided as a communication channel 12.

Messages UM.N, PL.N are exchanged between the test environment 10 and the device under test PL over the communication channel 12. The exchanged messages UM.N, PL.N can comprise time information such as time stamps. In this case, the time stamps can e.g., be derived from the time at which the messages are sent over the communication channel 12.

Environment messages UM.N are sent by the test environment 10 to the device under test PL and received by the device under test PL over the communication channel 12. In this case, the test environment 10 can read out specification messages VR.N from the first memory SP1 and send them to the device under test PL as environment messages UM.N. Device-under-test messages PL.N are sent by the device under test PL to the test environment 10 and received by the test environment 10 over the communication channel 12. In particular, the device under test PL can send the device-under-test messages PL.N as a response to the environment messages UM.N.

The communication of the device under test PL with the test environment 10 over the communication channel 12 includes the exchange of the messages UM.N, PL.N. The function implemented by the device under test PL can be tested by evaluating the messages UM.N, PL.N. In this case, the function of the device under test PL can be implemented in hardware and/or software.

The test environment 10 can store both the environment messages UM.N and the received device-under-test messages PL.N as memory messages SP.N in the second memory SP2. The test environment 10 monitors how the data UM.N sent by it are transmitted over the communication channel 12. One problem addressed by this application is the validation of these environment messages UM.N.

This validation takes place by comparing the environment messages UM.N as memory messages SP.N with the specification messages VR.N in a computer of the test environment 10. The environment messages UM.N are derived from the specification message VR.N. They are usually identical, but, depending on the communication channel 12, data frames or the length of data packets can be adapted, for example.

The environment message UM.N and the device-under-test message PL.N can be transmitted over the communication channel 12 in particular in accordance with the PTP protocol.

When comparing the memory message SP.N with the specification message VR.N, a respective time stamp contained in each message can be used for the comparison, but the content of each message can also be compared. Bitwise comparisons or correlation techniques can be used to determine correspondence of content, for example.

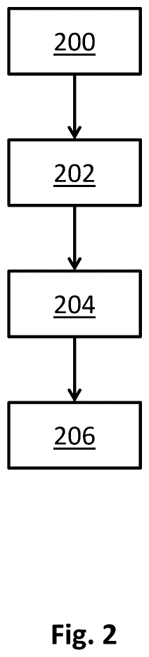

FIG. 2 is a flowchart of a schematic overview of a first embodiment of a method for verifying the communication over the communication channel 12. In step 200, a specification message VR.N is loaded by the test environment 10 from the memory SP1 and transmitted to the device under test PL as an environment message UM.N over the communication channel 12. This environment message UM.N sent over the communication channel 12 is stored by the test environment 10 in the second memory SP2. The messages PL.N coming from the device under test PL are also stored by the test environment 10 in this second memory SP2 (step 202).

In step 204, memory messages SP.N are then read out from the second memory SP2 by the test environment 10 in order to verify, in step 206, whether any such memory message SP.N corresponds to a specification. The specification comprises the stored specification messages VR.N which are saved in the memory SP1. The verification is then carried out using at least one memory message SP.N and at least one specification message VR.N. Therefore, a specification message VR.N is also loaded by the test environment 10 from the memory SP1. The specification message VR.N and the memory message SP.N can be compared on the basis of one or more features of these messages. One such feature is a respective time indication, which can be compared by establishing a difference, for example. However, the content of the messages, which is embodied in the payload data, can also be compared. To do so, the messages can be compared bit by bit, for example, or a suitable correlation technique can also be used.

It is also possible to compare each of a plurality of such features with one another in order to find the most closely corresponding specification message VR.N for a given memory message SP.N.

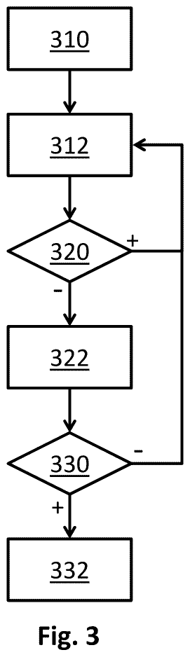

FIG. 3 is a flowchart of a schematic overview of a second embodiment of the method for verifying the communication. In step 310, a specification message VR.N is loaded from the memory SP1 and a memory message SP.N is loaded from the memory SP2. In step 312, the loaded specification message VR.N and the loaded memory message SP.N are then compared with regard to their time stamps by establishing a difference.

In step 320, the check is carried out as to whether the difference between the time stamps is above a threshold value. If that is the case (“+” path), the method returns to step 312, in order to load a further specification message VR.N from the first memory SP1 and compare it with the memory message SP.N, for example.

If it has been determined in step 320 that the difference between the two time stamps is less than or equal to the threshold value (“−” path), the method jumps to step 322, in order to check the sign of the difference. A check is carried out as to whether the difference is positive or negative. In step 330, a check is then carried out as to whether there has been a sign change in comparison with the previous check. This indicates that a minimum has been found for the differences between time stamps. Therefore, in such a case, i.e., when there has been a sign change (“+” path), the method jumps to step 332. In this case, the correct specification message VR.N has been found for the memory message SP.N, optionally in the preceding iteration step. There is accordingly a match. Therefore, the validation can take place in step 332.

If, however, it has been determined in step 330 that there has been no sign change (“−” path), the method returns to step 312 in order to load the next specification message VR.N and run through the above-described steps again.

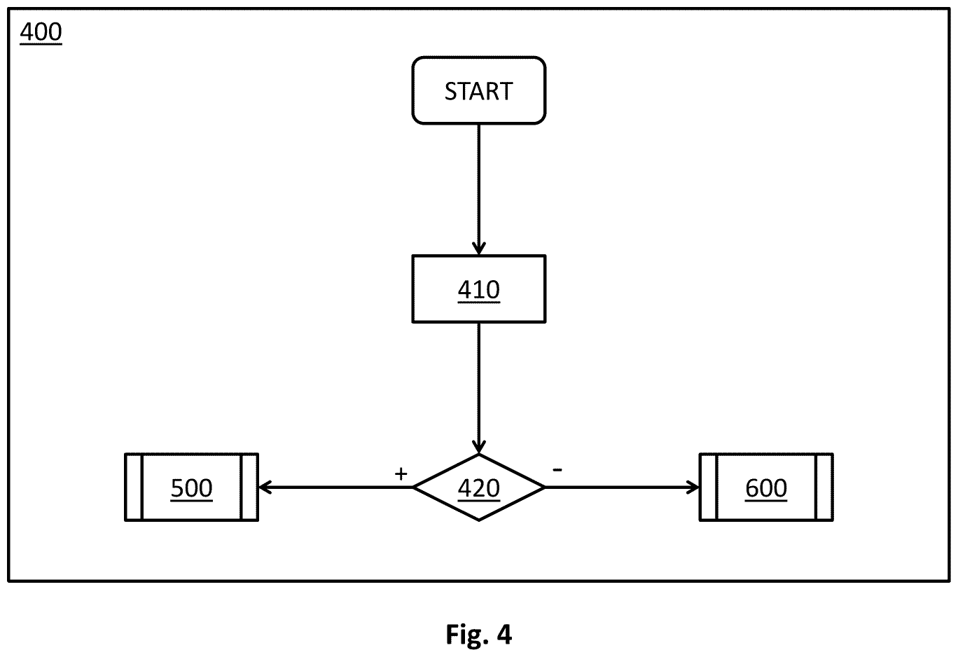

FIG. 4 is a flowchart of a schematic overview of a third embodiment of the method for verifying the communication. The method uses a list of specification messages VR.N and a list of memory messages SP.N and sorts elements of these lists, i.e., the messages in the lists, by criteria in a one-to-one relationship to one another. Elements that have too great a time difference from the next reasonable comparison element (configurable; e.g., >50 ms) are not associated and are discarded. The method starts with the value “false” for a variable CM. In the process, a candidate variable is filled with pairs of memory messages SP.N and specification messages VR.N and always stores the current best match of the candidates. The candidate variable thus comprises a particular memory message SP.N and a particular specification message VR.N as elements. The candidate variable is used as a comparison element during the method and is reset when an association is completed. Resetting involves invalidating both elements.

In block 400, the method begins at START, and in block 410, a specification message VR.N and a memory message SP.N are loaded from the memory SP1.

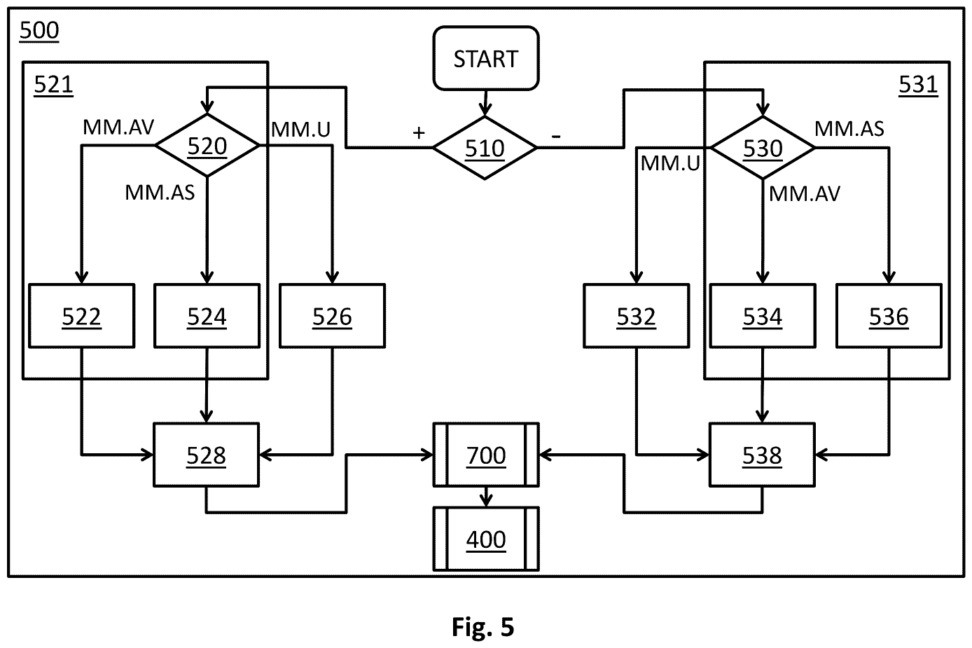

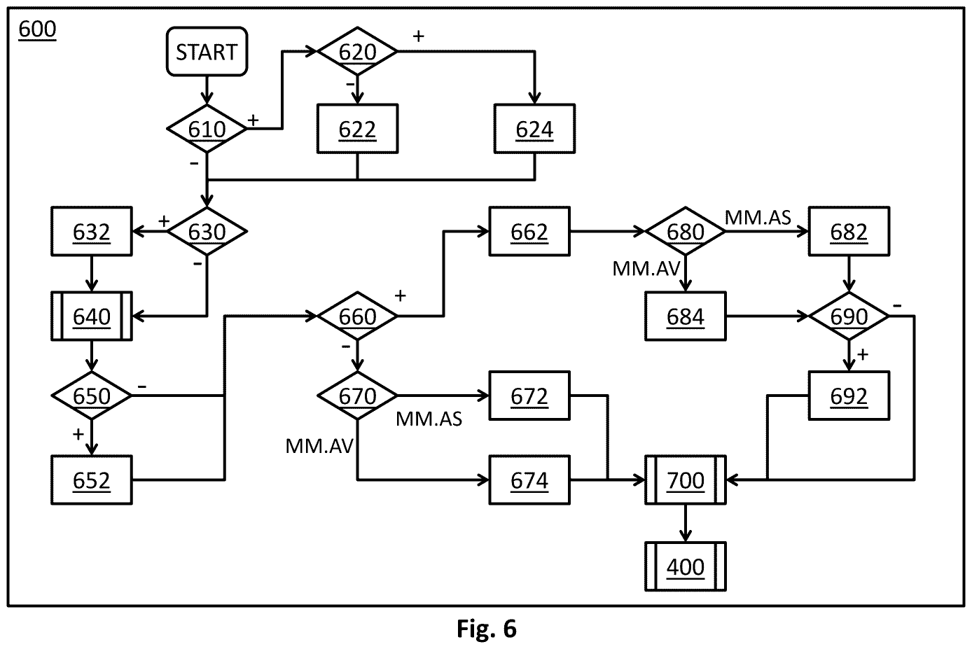

In 410, a new specification message VR.N is loaded if the current specification message VR.N is invalidated (FIG. 5 and FIG. 6). A new memory message SP.N is loaded if the current one is invalidated (FIG. 5 and FIG. 6).

In step 420, a check is carried out as to whether the time difference between the time stamps is above the threshold value. If this is the case (“+” path), the method jumps to block 500 (FIG. 5).

If, in step 420, the time difference is not above the threshold value (“−” path), the method jumps to block 600 (FIG. 6).

FIG. 5 schematically shows, by way of example, in the context of a flowchart, what happens in block 500 when the boundary condition from step 420 (FIG. 4) is fulfilled.

The method starts again at START, and in step 510 a check is carried out as to whether the time difference between the memory message SP.N and the specification message VR.N is greater than zero. If this is not the case (“−” path), the specification message VR.N is further in the future than the memory message SP.N, and the method jumps to block 531. In block 531, the method jumps to step 530. Block 531 comprises the steps 530, 534, 536, which are run through when there is a potential validation candidate among the verified messages.

In step 530, on the basis of the value of a variable MM, a decision is made as to whether the method jumps to step 532, 534, or 536. The variable MM indicates the mode which the method is in. It can assume three values:
a) MM.AV: the specification message VR.N is adapted when seeking the optimal candidate pair,
b) MM.AS: the memory message is adapted when seeking the optimal candidate pair,
c) MM.U: a mode has not yet been determined.

If the variable MM has the value MM.U, the method jumps to step 532, where the current specification message VR.N is retained. In step 532, there is no longer a potential validation candidate among the current messages.

If the variable MM has the value MM.AV, the method jumps to step 534. In 534, the variable CM is set to “true”. The specification message VR.N is retained for the next iteration.

If the variable MM has the value MM.AS, the method jumps to step 536. In 536, the current memory message SP.N is classified as an additional message without any counterpart among the specification messages VR.N.

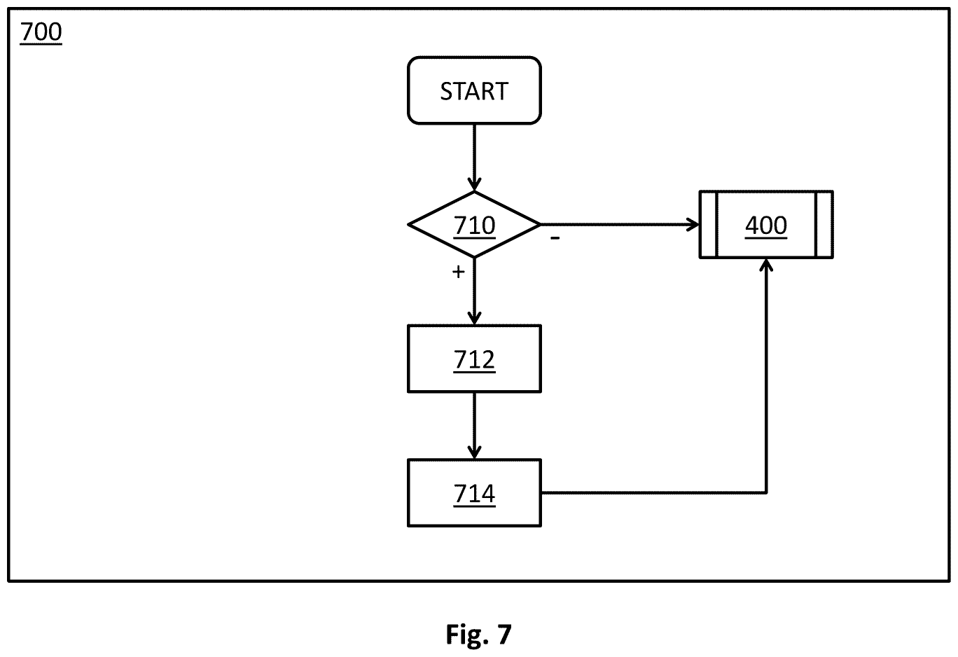

After each of steps 532, 534, 536, the method jumps to step 538. In step 538, which follows steps 532, 534, and 536, the memory message SP.N is invalidated, and the method then jumps to block 700 (FIG. 7).

Block 400 follows block 700 again.

If it has been determined in step 510 that the difference between the time stamps is in fact >0 (“+” path), the specification message VR.N is further in the past than the memory message SP.N, and the method jumps to block 521 and to step 520 therein. Block 521 comprises the steps 520, 524, 526, which are run through when there is a potential validation candidate among the verified messages.

In step 520, on the basis of the value of a variable MM, a decision is made as to whether the method jumps to step 522, 524, or 526.

If the variable MM has the value MM.U, the method jumps to step 526, where the current memory message SP.N is retained and the current specification message VR-N is dispensed with. In step 526, there is no longer a potential validation candidate among the current messages.

If the variable MM has the value MM.AS, the method jumps to step 524. In 524, the variable CM is set to “true”. The memory message SP.N is retained for the next iteration.

If the variable MM has the value MM.AV, the method jumps to step 522. In 522, the current memory message SP.N is classified as an additional message without any counterpart among the specification messages VR.N.

After each of steps 522, 524, 526, the method jumps to step 528. In step 528, which follows steps 522, 524, and 526, the specification message VR.N is invalidated, and the method then jumps to block 700 (FIG. 7).

Block 400 follows block 700 again.

FIG. 6 schematically shows an exemplary block 600. A method is presented as a flowchart, in which the specification messages VR.N and memory messages SP.N to be compared have a time difference that is not above the threshold value (FIG. 4).

The block 600 begins at START, and in step 610 a check is carried out as to whether the variable MM has the value MM.U.

If MM does have the value MM.U (“+” path), the method jumps to step 620, in which a check is carried out as to whether the time difference between the current memory message SP.N and specification message VR.N is greater than zero. If this is the case (“+” path), the method jumps to block 624, and the variable MM is set to the value MM.AR.

If it has been determined in step 620 that the time difference is less than or equal to 0 (“−” path), in block 622 the variable MM is set to the value MM.AS. Step 630 then follows steps 622 and 624.

If it has been determined in step 610 that the value of the variable MM is not equal to MM.U (“−” path), the method jumps directly from 610 to 630.

In step 630, a check is carried out as to whether the payload data lengths of the messages to be compared (memory message SP.N and specification message VR.N) are different. If this is the case (“+” path), the method jumps to 632, where a difference between the payload data lengths is ascertained.

If it has been determined in step 630 that the lengths of the payload data are the same (“−” path), the method jumps to block 640, in which a check is carried out as to whether there is a better candidate for a match. In this case, the time difference, the length of the payload data, and a difference between the payload data are checked. By checking the payload data, it can be ascertained whether the payload data have been corrupted. This can be indicated in a report on the method or together with the ascertained match, for example.

The method also jumps to block 640 after step 632.

Block 640 is followed by step 650, in which a check is carried out as to whether a termination condition is fulfilled. If this is not the case (“−” path), the method jumps to step 660. If this is the case (“+” path), the method jumps to step 652, where the memory message SP.N and specification message VR.N pair that is being compared is reset. In this case, the current identified match is stored with all the information, e.g., also relating to the content of the message, and the current candidate is invalidated.

The method also jumps to step 660 after step 652.

In step 660, a check is carried out as to whether MM has the value MM.AS and, at the same time, the time difference is less than zero, or whether MM has the value MM.AV and, at the same time, the time difference is greater than zero.

If this is not the case (“−” path), the sign has not changed in the time differences of the pair being compared, and the method jumps to step 670, in which the value of the variable MM is checked. If the variable MM has the value MM.AS, in 672 the memory message SP.N is invalidated in order to carry out the next pass with a new memory message SP.N for the pair to be tested. If the variable MM has the value MM.AV, in 674 the specification message VR.N is invalidated in order to carry out the next pass with a new specification message VR.N for the pair to be tested.

After both steps 672 and 674, the method jumps to block 700 (FIG. 7). Block 400 follows block 700 again.

If the check in step 660 is positive (“+” path), the method jumps to step 662, in which the variable CM is set to “true”. This is then followed by step 680.

In step 680, the value of the variable MM is checked. If the variable MM has the value MM.AS, in 682 the specification message VR.N is invalidated. If the variable MM has the value MM.AV, in 684 the memory message SP.N is invalidated. In step 690, a check is then carried out as to whether, in step 652, the pair to be compared has been reset.

If the check in step 690 is positive (“+” path), then in 692 both messages—the memory message SP.N and the specification message VR.N—are invalidated, since an optimal pair has in fact been found, and the next run starts with a new comparison pair. The method then jumps to block 700 (FIG. 7). If the check in step 690 is negative (“−” path), the method jumps directly to block 700 (FIG. 7). Block 400 follows block 700 again.

FIG. 7 is an exemplary schematic flowchart for the block 700, which starts at START. In 710, the variable CM is verified. If the variable CM has the value “true”, the method jumps to step 712 in order to determine the current match and then, in step 714, reset the current candidates. The variable CM for the pair to be tested is set to “false” and thus invalidated, and the variable MM is set to MM.U. The method then jumps to block 400 (FIG. 4).

If it has been determined in step 710 that the variable CM has the value “false” (“−” path), the method jumps directly to block 400 (FIG. 4).

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

List of Reference Signs

| | |
|---|---|
| 10 | Test environment |
| 12 | Communication channel |
| 14 | Test trip recording |
| SP1, SP2 | First memory, second memory |
| PL | Device under test |
| VR.N | Specification message |
| SP.N | Memory message |
| UM.N | Environment message |
| PL.N | Device-under-test message |
| MM.U, MM.AV, | Possible values of the |
| MM.AS | variable MM |
| 200-714 | Method steps |

1. A test system for testing a device under test, comprising:
an interface configured to exchange messages with the device under test over a communication channel in order to test the device under test; and
a processor configured to verify whether at least one message exchanged over the communication channel corresponds to a specification, wherein the specification comprises stored specification messages, and the verification comprises storing the messages exchanged over the communication channel as memory messages, wherein the verification is carried out using at least one memory message and at least one specification message.

2. The test system according to claim 1, wherein the messages comprise environment messages and device-under-test messages, wherein the test environment is configured to send the environment messages and receive the device-under-test messages from the device under test.

3. The test system according to claim 2, wherein the at least one memory message is an environment message.

4. The test system according to claim 1, wherein the test environment is configured to use a Precision Time Protocol (PTP) protocol for exchanging the messages over the communication channel.

5. A method for verifying a communication, wherein the method comprises:
reading out, by a test environment, memory messages, wherein the memory messages comprise stored messages exchanged with a device under test over a communication channel in order to test the device under test; and
verifying, by the test environment, whether at least one message exchanged over the communication channel corresponds to a specification, wherein the specification comprises stored specification messages, and wherein the verification is carried out using at least one memory message and at least one specification message.

6. The method according to claim 5, further comprising:
exchanging, by the test environment, the messages with the device under test; and
storing, by the test environment, the exchanged messages as memory messages.

7. The method according to claim 5, wherein at least one specification message is read out from a first memory and is sent over the communication channel as a message.

8. The method according to claim 5, wherein the verification is carried out using a time indication in the at least one memory message and in the at least one specification message.

9. The method according to claim 5, wherein the verification is carried out using the content of the at least one memory message and of the at least one specification message.

10. The method according to claim 5, wherein the verification comprises associating the at least one memory message with the at least one specification message.

11. The method according to claim 5, wherein the verification is carried out iteratively using a plurality of memory messages and a plurality of specification messages, wherein a respective memory message and a respective specification message are used in an iteration.

12. The method according to claim 11, wherein, in an iteration, a difference is established between the respective time indications of the memory message and the specification message, and, on the basis of a sign of the difference, the relevant memory message or the relevant specification message is used for a further iteration.

13. The method according to claim 12, wherein the respective memory message or the respective specification message is discarded based on the difference being above a threshold value.

14. The method according to claim 12, wherein the association is made when the sign of differences changes in successive iterations.

15. A non-transitory computer-readable medium having processor-executable instructions stored thereon for verifying a communication, wherein the processor-executable instructions, when executed, facilitate performance of the following:
reading out, by a test environment, memory messages, wherein the memory messages comprise stored messages exchanged with a device under test over a communication channel in order to test the device under test; and
verifying, by the test environment, whether at least one message exchanged over the communication channel corresponds to a specification, wherein the specification comprises stored specification messages, and wherein the verification is carried out using at least one memory message and at least one specification message.
